(19) United States
(12) Patent Application Publication
(10) Pub. No.: US 2015/0237753 A1
(43) Pub. Date: Aug. 20, 2015

(54) FRAME FOR AN OBJECT

(71) Applicant: THE IMPRESSARIO COMPANY LIMITED, Hong Kong (CN)

(72) Inventor: Christopher Bernard Wilcock, Hong Kong (CN)

(21) Appl. No.: 14/701,800

(22) Filed: May 1, 2015

Related U.S. Application Data
(63) Continuation of application No. PCT/CN2014/071973, filed on Feb. 11, 2014.
(60) Provisional application No. 61/763,613, filed on Feb. 12, 2013.

(51) Int. Cl. H05K 5/02

(52) U.S. Cl. CPC H05K 5/0247; H05K 5/0217

(57) ABSTRACT

A frame for an object comprising a frame body arranged to removably engage, support or operate with the object, wherein the frame body includes one or more functional modules each arranged to provide a processing or active function to the frame body or the object when the frame is engaging, supporting or operating with thereof; and wherein the frame body is further arranged to at least partially encompass or surround the object.

### TECHNICAL FIELD

The present invention relates to a frame for an object and particularly, although not exclusively, to a modular frame for a post manufacture modifiable electronic device.

### BACKGROUND

In many objects such as electronic devices, frames or frame structures may be included to support or to contain the components of electronic devices. The frames may also be used for protecting the internal components of the devices.

Devices relating to media, for example, digital photo frames, may be used for displaying media such as images on the built-in display screen. These devices may be programmed with instruction codes or software platforms stored in the internal memory of the device for processing and presenting the media data on the display screen.

In manufacturing process, these objects or devices may be mass produced with high degree of uniformity in the frames, the hardware and software components. These frames, hardware and software components are not modifiable or customizable after the completed manufacturing process.

### SUMMARY

In accordance with a first aspect of the present invention, there is provided a frame for an object comprising: a frame body arranged to removably engage, support or operate with the object, wherein the frame body includes one or more removable functional modules each arranged to provide a processing or active function to the frame body or the object when the frame is engaging, supporting or operating with thereof.

In an embodiment of the first aspect, the one or more removable functional modules are further arranged to interact with each other to provide the processing or active function to the frame body or the object.

In an embodiment of the first aspect, each of the one or more removable functional modules are arranged to intercommunicate with each other so as to provide a modular functional arrangement.

In an embodiment of the first aspect, the frame body is powered by an electric current delivered thereto to provide the processing or active function to the frame body or the object.

In an embodiment of the first aspect, the removable functional modules include a power module operable to deliver electric current to the frame body.

In an embodiment of the first aspect, the power module is an electric current generation apparatus built in or attached to the frame body.

In an embodiment of the first aspect, the one or more removable functional modules include at least one of a processing module, a controller module, a communication module, a display module, a storage module, an input module, an output module, a frame stand, or a space-occupying piece.

In an embodiment of the first aspect, the one or more removable functional modules include a frame-fittable item, being dimensioned to fit the frame body.

In an embodiment of the first aspect, further comprises an attachment means arranged to removably engage the frame-fittable item to the frame body.

In an embodiment of the first aspect, the attachment means is provided on one or more positions of at least one of the frame body or the frame-fittable item, wherein the one or more positions include at least one of an edge, a surface or a spot.

In an embodiment of the first aspect, the attachment means include at least one of a reversible tongue-and-groove fitting, a soft fastener, a sticky substance, an organic medium with separable adhesion, a magnetic medium or a electro-magnetic medium. The attachment means may also be any other known means of attachment arranged to removably engage multiple items, objects or parts.

In an embodiment of the first aspect, one or more removable functional modules are contained in a pan having a dimension which fits the frame body.

In an embodiment of the first aspect, one or more removable functional modules are sleeved in a structure having a dimension which fits the frame body.

In an embodiment of the first aspect, the frame body is at least one of a pan or a sleeve arranged to engage, support or contain the one or more removable functional modules.

In an embodiment of the first aspect, the frame body is powered by an electric current delivered from the frame-fittable item to provide the processing or active function to the frame body or the object.

In an embodiment of the first aspect, further comprising an external modular structure arranged to removably attach to the frame body, wherein the external modular structure is arranged to include the one or more external removable functional modules each arranged to provide the processing or active function to the frame body or the object.

In an embodiment of the first aspect, the one or more external removable functional modules include at least one of a power module, a processing module, a controller module, a communication module, a display module, a storage module, an input module, an output module, a frame stand or a space-occupying piece.

In an embodiment of the first aspect, the frame body is removably attach to a removable stand, and wherein the removable stand is manually or automatically expandable to accommodate a change in size of a part or an entire frame body.

In an embodiment of the first aspect, further comprising a cable operable to deliver electric current thereto, wherein the cable comprises one or more connectors and an encapsulation arrange to encapsulate the cable.

In an embodiment of the first aspect, the one or more connectors and the cable are separable among each other.

In an embodiment of the first aspect, the encapsulation is electronically controllable.

In an embodiment of the first aspect, the encapsulation includes at least one of a luminescent operable to be altered by an electrical voltage, a light-emitting diodes or an electro-chemical material.

In an embodiment of the first aspect, further comprises an identification module arranged to identify a user to personalize the frame in association with a user identification.

In an embodiment of the first aspect, the user identification includes at least one of a machine readable identifier or an optical identifier.

In accordance with a first aspect of the present invention, there is provided a method for interacting with a frame in accordance with the embodiment of the first aspect, comprising the steps of:
connecting one or more frames via a communication network to form a virtual machine; and
interacting with the virtual machine to manipulate the processing or active functions of the one or more frames or objects.

In an embodiment of the second aspect, further including a step of connecting the one or more frames to a processing module via the communication network to form the virtual machine.

In an embodiment of the second aspect, at least a part of the virtual machine resides in at least one of the one or more frames.

In an embodiment of the second aspect, the virtual machine is operable to communicate with at least one distributed computing network arranged to process data before a presentation of the data in at least one of the virtual machine, the one or more frames or the objects.

In an embodiment of the second aspect, at least a part of the distributed computing network resides in the one or more frames and/or the virtual machine.

In accordance with a third aspect of the present invention, there is provided a frame for an object comprising: a frame body arranged to removably engage, support or operate with the object, wherein the frame body includes one or more functional modules each arranged to provide a processing or active function to the frame body or the object when the frame is engaging, supporting or operating with thereof; and wherein the frame body is further arranged to at least partially encompass or surround the object.

In an embodiment of the third aspect, at least two of the one or more functional modules are further arranged to interact with each other to provide the processing or active function to the frame body or the object.

In an embodiment of the third aspect, at least two of the one or more functional modules are arranged to intercommunicate with each other so as to provide a modular functional arrangement.

In an embodiment of the third aspect, the frame body is powered by an electric current delivered thereto to provide the processing or active function to the frame body or the object.

In an embodiment of the third aspect, the functional modules include a power module operable to deliver the electric current to the frame body.

In an embodiment of the third aspect, the one or more functional modules include a frame-fittable item being dimensioned to fit the frame body.

In accordance with a fourth aspect of the present invention, there is provided a method for interacting with a frame in accordance with the third aspect, comprising the steps of:
connecting one or more frames via a communication network to either form or augment a virtual machine; and
interacting with the virtual machine to manipulate the processing or active functions of the one or more frames or objects.

In an embodiment of the fourth aspect, the method further includes a step of connecting the one or more frames to a processing module via the communication network to form the virtual machine.

In an embodiment of the fourth aspect, at least a part of the virtual machine resides in at least one of the one or more frames.

In an embodiment of the fourth aspect, the virtual machine is operable to communicate with at least one distributed computing network arranged to process data before a presentation of the data in at least one of the virtual machine, the one or more frames or the objects.

In an embodiment of the fourth aspect, at least a part of the distributed computing network resides in the one or more frames and/or the virtual machine.

In an embodiment of the third aspect, the frame further comprises an attachment means arranged to removably engage the frame-fittable item to the frame body.

In an embodiment of the third aspect, the attachment means is provided on one or more positions of at least one of the frame body or the frame-fittable item, wherein the one or more positions include at least one of an edge, a surface or a spot.

In an embodiment of the third aspect, the attachment means include at least one of a reversible tongue-and-groove fitting, a soft fastener, a sticky substance, an organic medium with separable adhesion, a magnetic medium or an electro-magnetic medium.

In an embodiment of the third aspect, the one or more functional modules are contained in a pan having a dimension which fits the frame body.

In an embodiment of the third aspect, one or more functional modules are sleeved in a structure having a dimension which fits the frame body.

In an embodiment of the third aspect, the frame further comprises an external modular structure arranged to removably attach to the frame body, wherein the external modular structure is arranged to include the one or more external functional modules each arranged to provide the processing or active function to the frame body or the object.

In an embodiment of the third aspect, the one or more functional modules include at least one of a power module, a processing module, a controller module, a communication module, a display module, a storage module, an input module, an output module, a frame stand, or a space-occupying piece.

In an embodiment of the third aspect, the frame body is removably attach to a removable stand, and wherein the removable stand is manually or automatically expandable to accommodate a change in size of a part or an entire frame body.

In an embodiment of the third aspect, the frame further comprises a cable operable to deliver electric current thereto, wherein the cable comprises one or more connectors and an encapsulation arrange to encapsulate the cable, and wherein the one or more connectors and the cable are separable among each other.

In an embodiment of the third aspect, the encapsulation is electronically controllable.

In an embodiment of the third aspect, the frame further comprises an identification arrangement arranged to facilitate the association of an identity of a user of the frame to an identity of the frame.

In one embodiment, the identification arrangement may include a barcode, QR code, alpha identifier, numerical identifier, alphanumeric identifier or any one or more thereof.

In an embodiment of the third aspect, the identification arrangement is arranged to associate the identity of the user to the identity of the frame by obtaining a user identifier via an external authenticated device.

In an embodiment of the third aspect, the frame body is arranged to operate with the object via a wireless communication network between the frame body and the object.

In an embodiment of the third aspect, the frame body is arranged to operate with the object without a physical contact or engagement.

### BRIEF DESCRIPTION OF THE DRAWINGS

Embodiments of the present invention will now be described, by way of example, with reference to the accompanying drawings in which:

FIG. 1 is a schematic diagram of a frame for an object in accordance with an embodiment of the present invention;

FIG. 2 is a schematic diagram of a frame for an object in accordance with an embodiment of the present invention;

FIG. 3A is a zoom-in view of a corner of the frame and a reversible tongue-and-groove fitting provided at the corner of the frame of FIG. 2;

FIG. 3B is a zoom-in view of a corner of the frame and a continuous strip of means of adhesion provided at the corner of the frame of FIG. 2;

FIG. 3C is a zoom-in view of a corner of the frame and a plurality of partial strips of means of adhesion provided at the corner of the frame of FIG. 2;

FIG. 3D is a zoom-in view of a corner of the frame and an embedded magnetic medium provided at the corner of the frame of FIG. 2;

FIG. 4A is a schematic diagram of a frame for an object in accordance with an embodiment of the present invention;

FIG. 4B is a schematic diagram showing a pan containing a plurality of functional modules of the frame of FIG. 4A;

FIG. 5 is a schematic diagram of a frame for an object in accordance with an embodiment of the present invention; and

FIG. 6 is a schematic diagram of a method for interacting with one or more frames associated with a virtual machine and a distributed computing network in accordance with an embodiment of the present invention.

### DETAILED DESCRIPTION OF THE PREFERRED EMBODIMENT

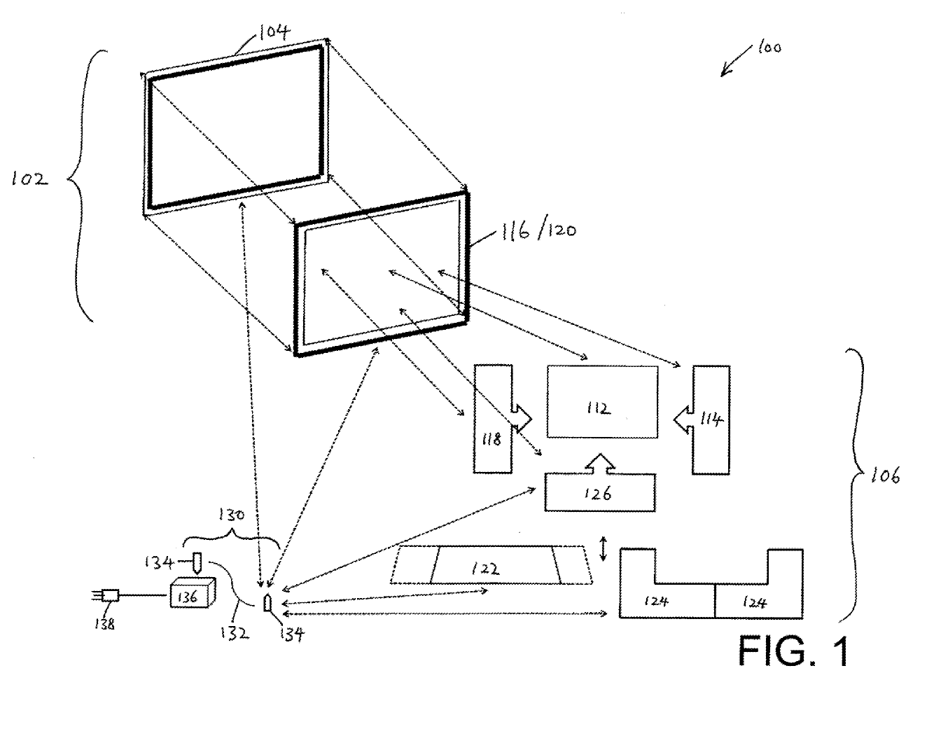

Referring to FIG. 1, there is provided an embodiment of a frame 102 for an object 100 comprising: a frame body 104 arranged to removably engage, support or operate with the object 100, wherein the frame body 104 includes one or more removable functional modules 106 each arranged to provide a processing or active function to the frame body 104 or the object 100 when the frame 102 is engaging, supporting or operating with thereof.

In this embodiment, the frame 102 includes a frame body 104 and at least one removable functional module 106, such as a display assembly, a circuit board, or other components arranged to provide a function to the frame body 104 or the object 100.

The frame 102 may provide a mechanical support to an object 100, which may, in some examples, comprise a hard material or structure to provide the object a predefined shape. The frame 102 may also be arranged to hold one or more components of the object 100 in a predetermined positions. For example, in a television, the processing and controlling modules may be placed at the back of a display screen, the speakers may be placed at the two sides of the display screen, and these components are further encapsulated by a frame of the television with ports and connectors exposed to some predefined openings on the frame.

The frame 102 may also include an adjustable supporting mechanism such that the object 100 may be placed or positioned in different ways, for example, a television with a frame including a stand may be placed on a flat surface, or may be mounted to another adjustable frame with the mounting fasteners on the frame.

Besides mechanical supports, the frame 102 may incorporate other components to provide functions to the object 100, such as indicators or an auxiliary display screen for notifying users the operating condition of the object 100, one or more input switches for controlling the operation of the object 100. The frame 102 may also include a camera module embedded in the frame to retrieve images or video, which may then be transferred to a processing module for processing.

Another example is that, electronic components may be contained in frame bodies of wearable devices such as smart glasses and smart watches, to provide processing or active functions such as display functions in the frame body of such wearable devices.

The frame body 104 may also operate with the object 100 via a wireless communication network between the frame body and the object. In such arrangement, there are no physical contacts or engagements between the frame body 104 and the object 100, which allows a frame body 104 to provide a processing or active function to the object 100, while being physically apart from the object 100 within an operation range of the wireless communication network. Preferably, the wireless communication network includes at least one of a Bluetooth communication network, a Wi-Fi communication network, an near-field communication (NFC) network, an infra-red communication network, a radio-frequency (RF) communication network, or any other wireless communication network known by a person skilled in the art.

Although the term “frame” may imply that the frame is a structural arrangement which may support or integrate with an associated object, in this disclosure, the term “frame” may also include other examples of structures, members or arrangements which may not necessarily support or integrate with an associated object, but may simply attach or engage itself with the associated object. In some examples, the frame, may also include a housing or a cover for the object, or in some other examples, a holder, a clip or a fastening means such as a module holding pan, sleeve or the like.

In this example embodiment, the removable functional module 106 may be a part of a core 112 of the object 100, which may comprises a processing module or a controller module. The removable functional module may be a communication module 114 arranged to communicate with other objects or devices, which may comprise a SIM module, a network module, an IP module, a Wi-Fi module, a Bluetooth module, an Ethernet module or a near-field communications (NFC) module. The removable functional module 106 may be a display module 116 such as a display screen assembly, a light emitting device or an indicator. The removable functional module 106 may be a storage module 118 such as a volatile memory device or a non-volatile memory device. The removable functional module 106 may also be an input module 120 or an output module such as a touch-sensitive screen, a pointing device, a keyboard, a speaker, an optical imaging device, a printing device, etc.

In some example embodiments, the removable functional module 106 is a stand 122 or a cradle 124 such that the frame 102 or the object 100 may rest on the stand 122 or the cradle 124. Preferably, the stand 122 or the cradle 124 may be arranged to intermediate electric power to the object 100 or the frame 102 of the object 100 such that the frame 102 is operable to provide the processing or active function. For example, an instrument of display 100 may be formed by attaching the frame 102 to a stand 122. Preferably, the stand 122 or the cradle 124 may be either fixed-size or expandable to accommodate an increase or decrease in size of either a part of or an entire frame 102 or an object 100.

In yet another example embodiment, the removable functional module is a power module 126 arranged to deliver electric current to the frame body 104 and/or the frame 102 such that the frame body 104, the frame 102 and/or the object 100 is operable to provide the processing or active function. For example, the power module 126 may be a power pack comprising one or more batteries, an AC-DC transformer, or other powering apparatus such as a solar cell or a fuel cell.

The removable functional module 106 may also be a space-occupying piece. The space-occupying piece may be one or more empty shells, duplicating forms of other removable functional modules 106, to substitute, prosthesis-like, respectively, for one or more different modules 106, to fill the space that each such actual module 106 would occupy in the frame 102 or the device or the computer, in order to duplicate the footprint of the full suite of modules 106. Alternatively, the space-occupying piece may be considered as a weight-saving module such that the frame 102 installed with the weight-saving module may have be lighter than that installed with another removable functional module 106 filling the same space or volume.

Each of the one or more removable functional modules 106 may also be arranged to interact with each other to provide a processing and/or active function to the frame 102 or the object 100. In other words, functions respective to two or more of the removable functional modules 106 can, instead, reside in a single module, for example, a module that is a cradle cum stand cum power pack, while still allowing for modularity.

The affixation of a removable functional module 106 or several modules 106, individually, or a complement of different modules 106 to a complementary item of a frame 102 or an object 100, for example, the back of an instrument of display 116, can be achieved, by using permanent fasteners, or non-permanent fasteners such as tongue-and-groove fittings 202 or some form of adhesion 212 or soft fastener(s), with reference to the attachment means provided in some example embodiments to achieving separability of the removable functional modules 106 of a frame 102 in an object 100, and whether the affixation of modules 106 is one by one or collectively, after having arranged the modules 106 together on a sufficient plate to affix in one piece to the complementary item.

Alternatively, each of the one or more removable functional modules 106 are arranged to intercommunicate with each other so as to provide a modular functional arrangement. In other words, each such module 106, upon addition to device or object 100 or frame 102, can be utilized by the respective device or object 100 or frame 102, as a result of electric/electromagnetic/electronic communications, via one or more electronic contacts, or a wireless communication, between the respective module 106 and the other module(s) to which that module fits.

For example, by utilizing an already available means of electronic communications, whether by wire or wireless, one module 106 can affect another module 106 without having to be integrated with it: for example, for the communication between the core 112 and an instrument of display 116 that is remote to the core.

Optionally, each such module 106, including the components therein, can consist of already available apparatus or functional module in relation to the role of the module in the respective frame or object. For example, an additional processing module 112 may be included to enhance the processing power of the frame 102.

In an example embodiment, the frame 102 for an object 100 may comprises a cable 132 operable to deliver electric current thereto, wherein the cable 132 comprises one or more connectors 134 and an encapsulation arrange to encapsulate the cable 132. Preferably, the one or more connectors 134 and the cable 132 are separable among each other.

The cable 132, which may be a power cord 130 of the frame 102 or the object 100, is in modular structure or is modifiable. For example, the outermost encapsulation of the cable 132 may be variable, and the connectors 134 may be modified to a suitable connector, such as a USB connector or any other connector as known by persons skilled in the art.

The power cord 130 may connect directly with the power pack 126 or to an intermediating part, for example, a stand 122 or a cradle 124 that passes the current onward to the power pack 126. Alternatively, the power cord 130 may connect a frame 102 with a source of power. The source of power may be an AC-DC transformer 136 apparatus that, via a plug 138, connects to a point of source of the ultimate power (e.g. a wall socket), a recharger, or another power-providing appliance such as a USB port or a computer system.

Preferably, the connection by the power cord 130 at the frame 102 or the object 100 and the connection by the power cord 130 at the source of power can be by either USB jack or the equivalent. The power cord 130 or the cable 132 may utilize such alternative(s) and/or substitute(s) and/or successor(s) of the USB, as well, to the same purpose as USB jacks, as the alternative(s) or substitute(s) or successor(s) to USB may either be or become available to transmit sufficient current between any of electronic appliances, other devices, computers or the frame 102 for an object 100.

The encapsulation may encapsulate an electric wire in a ribbon, so that the ribbon is separable (attachable and removable) from a self-contained insulated wire, by either a person, whether a manufacturer or mercantile or a natural person, or a machine. That ribbon may consist of a material clear or of some or another colour. The electric wire is self-contained, so that the separability of the ribbon doesn't affect the wire.

In some example embodiments, the encapsulation is electronically controllable. For example, variation of the appearance of the encapsulation may be achieved either by separability of the encapsulation from the encapsulated wire to allow for selection among different encapsulating material or by electronic instruction, the latter so far as that the encapsulating material consists of sufficient material that can be variable or controllable electronically: for example, by alteration of very low voltage into the encapsulating material to make it luminescent or utilization of light-emitting diodes (LEDs) or electro-chemical reaction. Preferably, the variations of the appearance of the encapsulation may be affected manually or automatically, or may be affected by a controller module of the frame or the object, or any other controller module in communication with the encapsulation or the cable 132.

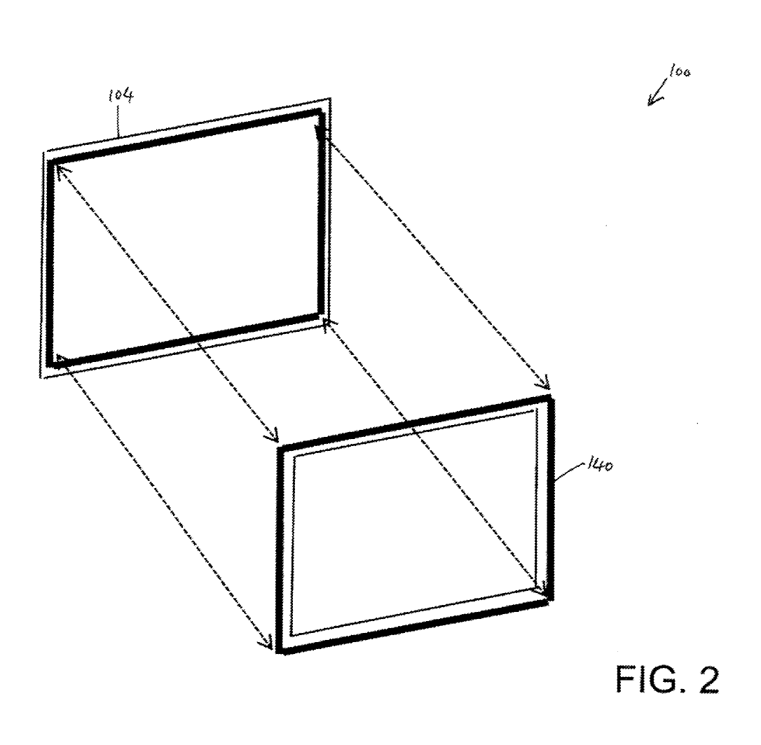

Referring to FIG. 2, there is provided an embodiment of a frame 102 for an object, wherein one or more removable functional modules 106 is a frame-fittable item 140 being dimensioned to fit the frame body 104.

In this embodiment, a frame-fittable item 104 may have a dimension which matches the empty area encompassed by the frame body 104, such that the frame-fittable item 104 filled the empty area. For example, a display screen may fit a frame in a digital photo frame.

Preferably, the frame body 104 comprises one or more attachment means arranged to separably attach the at least one frame-fittable item 140 to the frame body 104, and the attachment means provide a mechanism for attaching the frame body 104 and the frame-fittable item 140, while allowing for removing them from each other, through one or a combination of some or a combination of all of the following embodiments of the attachment means.

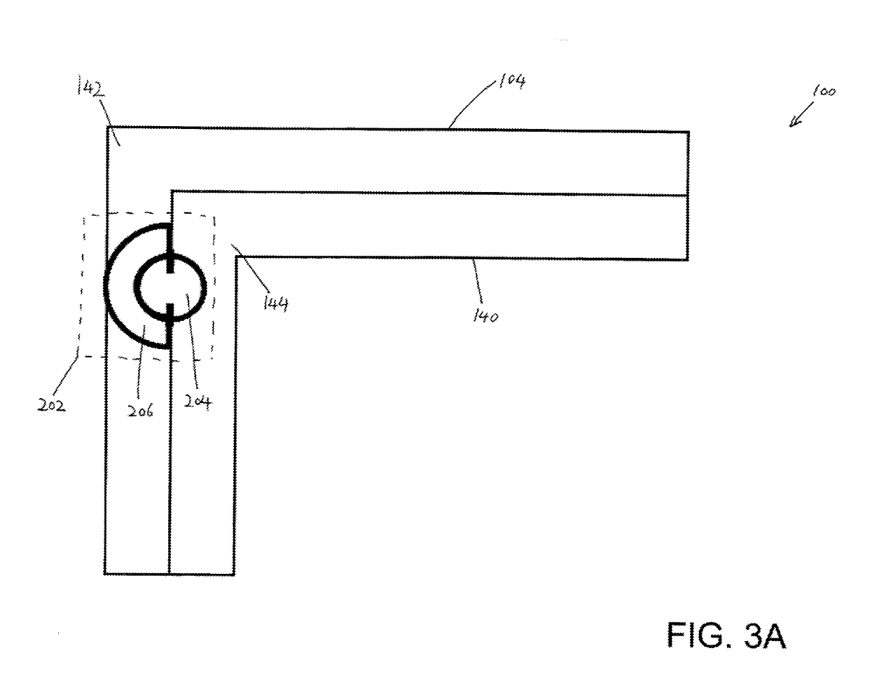

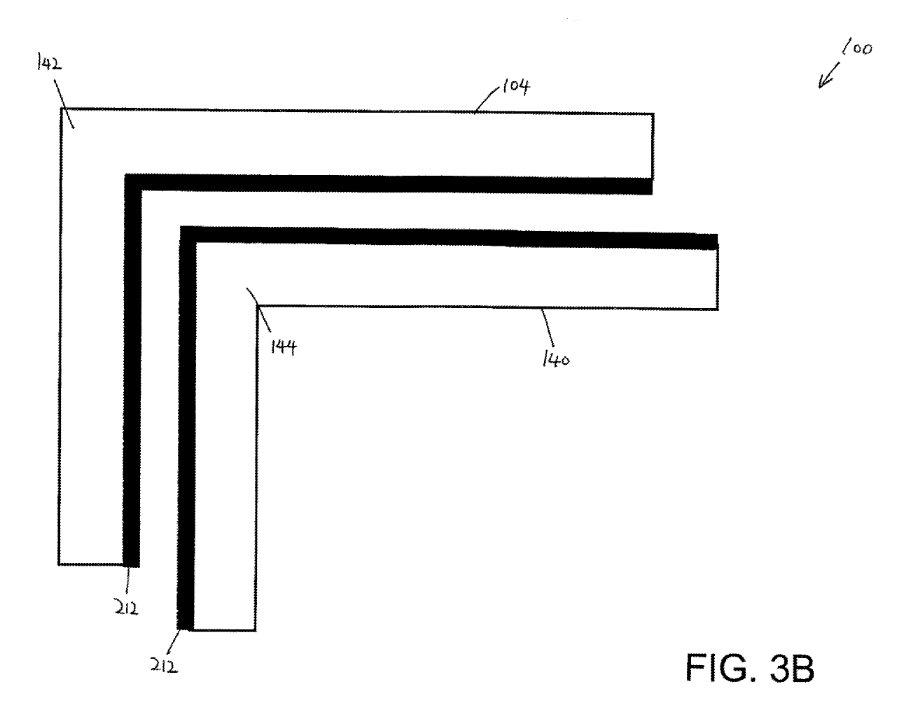

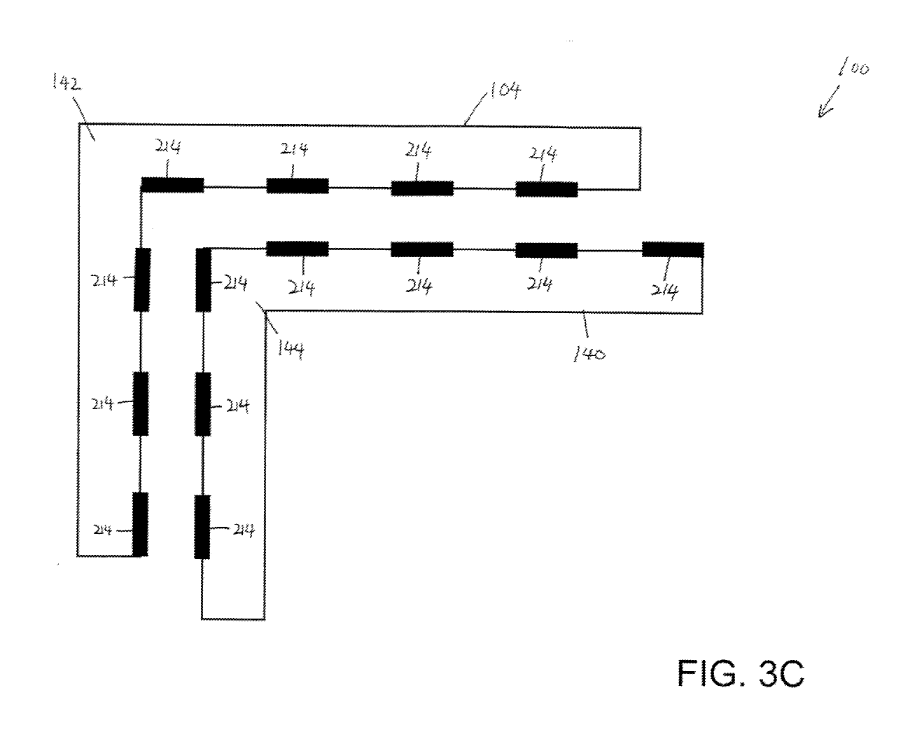

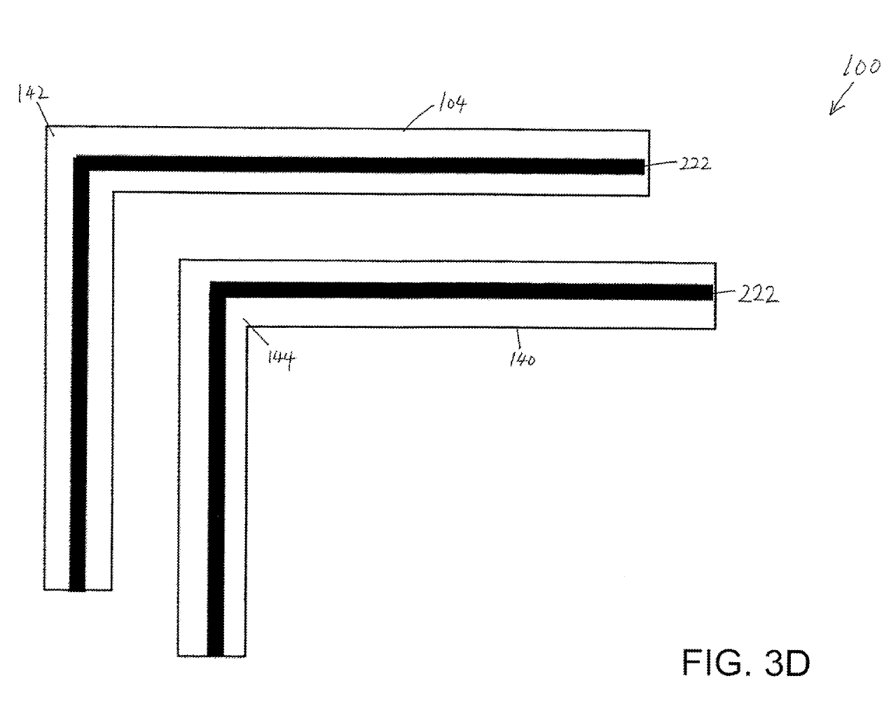

With reference to FIG. 3A, there is provided an embodiment of an attachment means which is a reversible tongue-and-groove fitting 202, a sufficient number of points on both the carve-out of the frame body 104 and the perimeter of the frame-fittable item 140 (for example, at each of a corner 142 of the frame and a corner of frame-fittable item 144, respectively), in order to securely keep the frame body 104 and frame-fittable item 140 together, with the option of introducing the fittings from the back of the frame 102 so that the fittings don't mar the look of the front of the frame 102.

In this embodiment, a tongue-shaped attachment means 204 is provided on a corner of a frame-fittable item, and may fit with a groove 206 provided on a corresponding position on a frame body 104 such that the frame body 104 and the frame-fittable item 140 is attached together. The frame-fittable item 140 may later be dethatched from the frame body 104 by disengaging the tongue-and-groove fitting 202. Alternatively, the corresponding position of the groove 206 and the tongue 204 may be interchangeable.

In some embodiments, the attachment means may be soft fasteners, for example, plastic male-to-female fasteners that allow for insertion and removal of the male to/from the female with suitable force, while being secure enough to keep the frame and the fittable-item together.

In some other embodiments, the attachment means may be an adhesion 212 that allows for separability of the frame body 104 and frame-fittable item 140 either upon application of either a suitable amount of force to bring the frame body 104 and frame-fittable item 140 together, to remain so until relaxation of the adhesion 212, or to relax the adhesion 212 by pulling the frame body 104 and frame-fittable item 140 apart. The adhesion 212 may be achieved by means of a suitable sticky substance or some organic medium which is suitable to achieving the separable adhesion.

Preferably, the separable adhesion 212 may also be a magnetic medium or an electro-magnetic medium at least one of the frame body 104 or the frame-fittable item 140, with a magnetism-responsive complement on the other of the frame body 104 or the frame-fittable item 140. The magnetism can either be inherent in that magnetic medium, thus resulting in adhesion still amenable to separability upon application of suitable force, or activated by sufficient electric current. The electric current can provided into the magnetic medium by means of either by or through the frame-fittable item 140, so far that it conducts power, alternatively, by or through the frame body 104, so far as that it conducts power. The electric current may be delivered to either whichever of the frame body 104 or the frame-fittable item 140 the electro-magnetic medium resides with.

With reference to FIG. 3B, there is provided an embodiment of an attachment means which is a continuous strip of means of adhesion 212, an adhesion 212 that allows for separability of the frame body 104 and frame-fittable item 140 either upon application of either a suitable amount of force to bring the frame body 104 and frame-fittable item 140 together, to remain so until relaxation of the adhesion 212, or to relax the adhesion 212 by pulling the frame body 104 and frame-fittable item 140 apart.

Alternatively, with reference to FIG. 3C, there is provided an embodiment of an attachment means which is one or more partial strips of means of adhesion 214. Similar to the embodiment as shown in FIG. 2B, the attachment means 214 allows for separability of the frame body 104 and frame-fittable item 140 either upon application of either a suitable amount of force to bring the frame body 104 and frame-fittable item 140 together, to remain so until relaxation of the adhesion 214, or to relax the adhesion 214 by pulling the frame body 104 and frame-fittable item 140 apart. Alternatively, the attachment means may be provided in spots.

With reference to FIG. 3D, there is shown an embodiment attachment means 222 embedded in at least one of a frame body 104 or a frame-fittable item 140. Such arrangement is particularly advantageous for, although not limited to, a magnetic medium or an electro-magnetic medium arranged to reside in the frame body 104 or the frame-fittable item 140.

Preferably, the introduction the means of adhesion can be, depending on the requirement(s) to make the adhesion, in one of several configurations: (a) the frame body 104 only; (b) the frame-fittable item 140 only; (c) both the frame body 104 and the frame-fittable item 140, whether at corresponding points on each or complementary points on each.

Preferably, depending on the type of fastener or means of adhesion, one or more fastener(s) or a medium of adhesion may reside in any of the permutations of the following introductions of the fastener or means of adhesion: (a) along the edge of the interior of the carve-out in a frame body 104; (b) on the back of a frame body 104; (c) along the edge of the perimeter of a frame-fittable item 140; (d) on the surface of a frame-fittable item 140 that can meet the back of a frame body 104; (e) within a frame body 104; (f) within a frame-fittable item 140.

Alternatively, the attachment means may also be any other known means of attachment arranged to removably engage multiple items, objects or parts. Optionally, multiple attachment means may be provided on multiple positions on each of the frame body and/or the frame-fittable item 140, to increase the security of the attachment between the frame body 104 and the frame-fittable item 140.

In some example embodiments, with respect to a method of adhesion, the element(s) of adhesion may be placed on the respective surface(s) there by one of several ways, including but not limited to: (a) whether in the course of or after the manufacture of the frame body 104, affix either spots of the element(s) of adhesion or a strip that contains the element(s) on the periphery of the carve-out of the frame body 104, or, conversely, to the frame-fittable item 140, in the course of or after manufacture of it; (b) whenever the means of adhesion need complements on both the frame body 104 and the frame-fittable item 140, likewise affix either the spots of the element(s) of adhesion or a strip that contains the element(s) to the perimeter of the frame-fittable item 140, in the course of or after the manufacture of the frame-fittable item 140, in addition to affixing either the spots of the element(s) of adhesion or a strip that contains the elements to the frame body 104, as above; (c) whenever utilizing a magnetic medium, embed it within, rather than affix it on, the periphery of the carve-out of the frame body 104 and the complement within the perimeter of the frame-fittable item 140, so as to conceal the means of adhesion, or the converse in respect of the frame body 104 and frame-fittable item 140.

In tandem with any of the above methods of attaching the frame body 104 and the frame-fittable item 140, the following alternatives may be provided, including but not limited to: (a) the frame-fittable item 140 may slip into the frame body 104; (b) the frame body 104 may slip onto the frame-fittable item 140; (c) the frame body 104 may open, jaw-like, on a hinge (secreted in the frame body 104 in such a way as avoid marring the front of the frame body 104) in order to embrace the frame-fittable item 140 as the frame body 104 closes around it.

Preferably, a frame body 104 and a respective frame-fittable item 140 may not be rectangular, as long as that the frame body 104 and the frame-fittable item 140 fit with each other. In addition, these methods of achieving separability of a frame body 104 and frame-fittable item body 104 can be in a variety of form factors.

In the case of the fastener or adhesion, as provided by an embodiment as described above, the suitable force necessary to close or undo the fastener or adhesion may be set, by the specification of the fastener or the means of adhesion, in keeping with whether a natural person or a machine is closing or undoing the fastener or adhesion.

Preferably, an electric current may be provided to empower energy-requiring functionality of the frame body 104 where the frame provides for such functionality. The necessary current may be supplied by or through or from any of a frame-fittable item 140 or an appliance or other device or computer therewith, through ordinarily available means of providing current from one appliance or other device or computer to another, or from within the frame body 104 itself, by means of for example, one or more batteries or by solar energy apparatus or tapping into wall power.

Preferably, a larger frame body 104 and a second smaller frame body 104 can fit together, irrespectively of whether or not the larger frame body 104 fits, as well, with the ultimate frame-fittable item 140: for example, while not exclusively, the larger frame body 104 provides a fixation of the assembly and the smaller frame body 104 provides an aesthetic addition or functional addition or interchangeability of the frame-fittable item 140 or intermediation of a different shape of carve-out of the ultimate frame body 104 and the ultimate frame-fittable item 140. Alternatively, a smaller frame body 104 may be arranged to secure the frame-fittable item 140 and an aesthetic larger frame body 104 may fit around the smaller frame body 104.

In an example embodiment, the frame body 104 and the frame-fittable item 140 may make up an object 100 or device per se, not part of an appliance or other device or computer: for example, as parts of eyeglasses or as parts of a piece of luggage or as parts of a piece of furnishings.

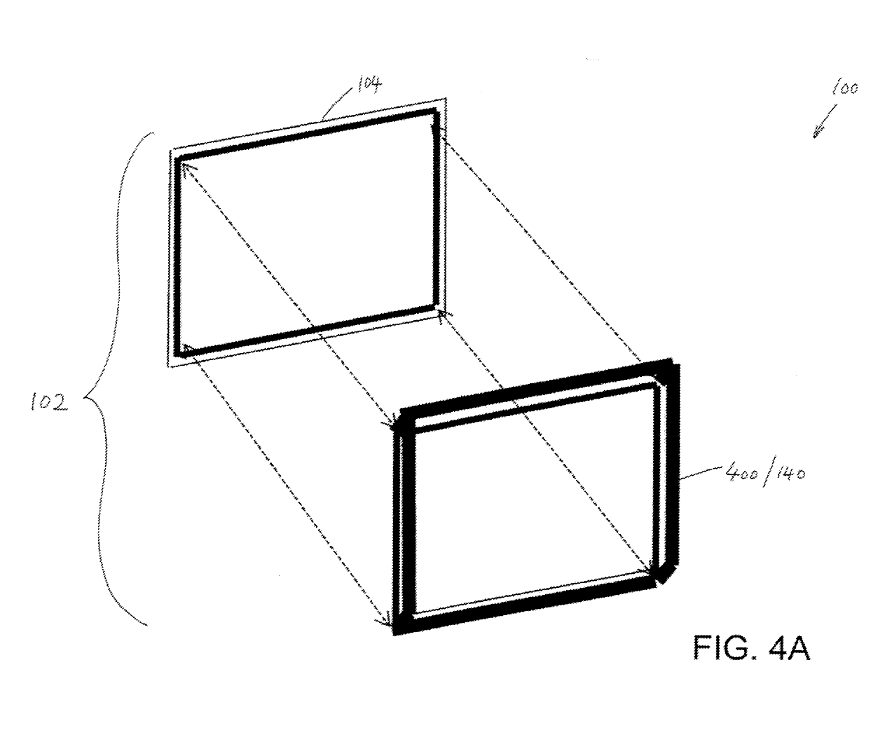

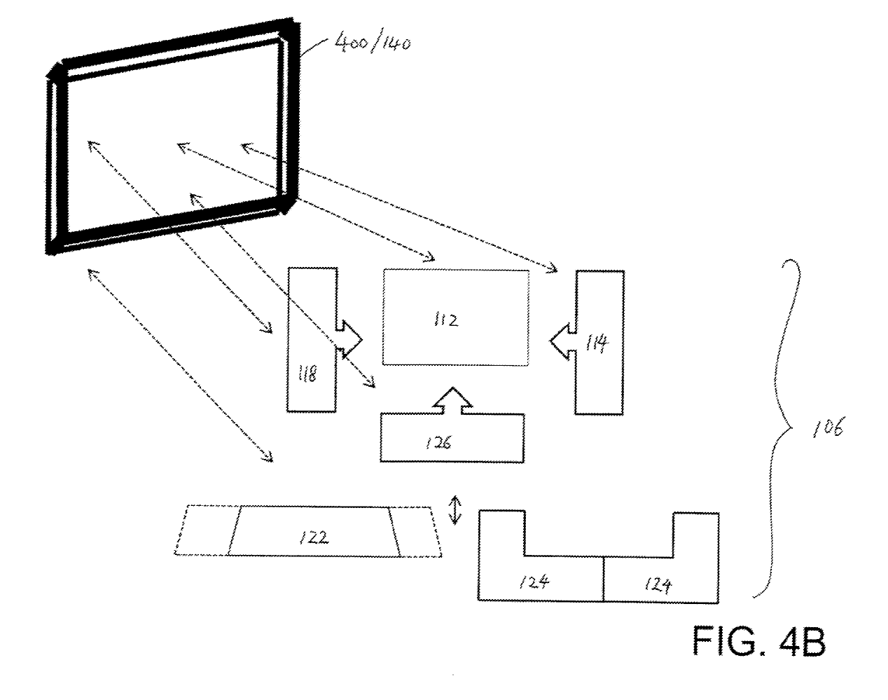

Referring to FIGS. 4A and 4B, there is provided an embodiment of a frame 102 for an object 100 comprising one or more removable functional modules 106 contained in a pan 400 having a dimension which fits the frame body 104. In this embodiment, the pan 400 may be considered as a frame-fittable item 140 as shown in the previous embodiments and is arranged to fit or attach with the frame body 104. Optionally, the modules 106 or components resides in the pan 400 may also be modular, and the pan 400 itself may also be modular, in order to facilitate either standardization or customization of the fittability with interchangeable frame body(s) 104.

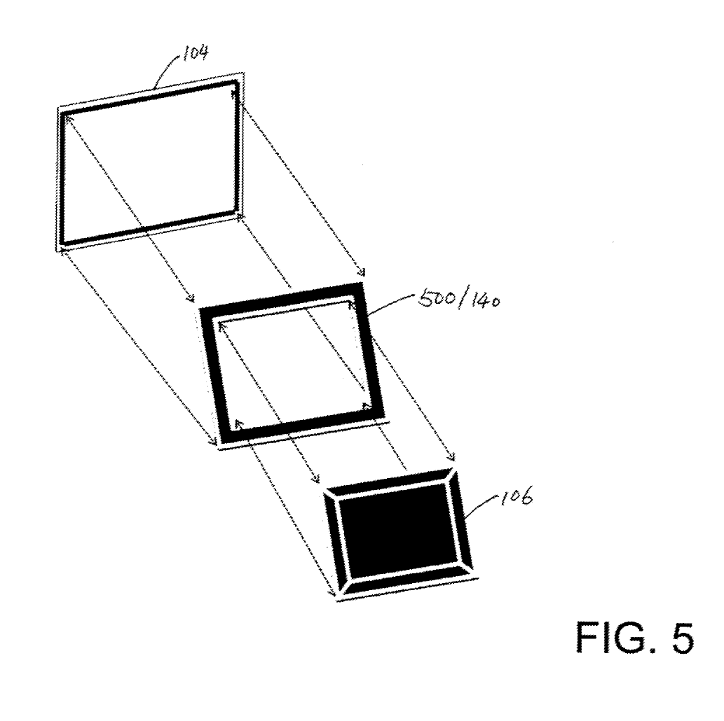

Referring to FIG. 5, there is provided an embodiment of a frame 102 for an object 100 comprising one or more removable functional modules 106 being sleeved in a structure 500 having a dimension which fits the frame body. In this embodiment, the sleeve 500 may be considered as a frame-fittable item 140 as shown in the previous embodiments and is arranged to fit or attach with the frame body 104. Optionally, the modules 106 or components resides in the sleeve 500 may also be modular, in order to facilitate either standardization or customization of the fittability with interchangeable frame body(s) 104.

For example, the standardization may be achieved by residing an instrument of display 116 (e.g. a screen) within the sleeve 500. Thus the sleeve 500 intermediates with the interchangeable frame body(s) 104, so as to preclude both (a) a maker or assembler or seller of frame body 104(s) having to anticipate various sizes of instruments of display 116 to fit with the frame body 104, so long as the instrument of display 116 sits within a sleeve 500 the specifications of which the maker or assembler or seller of the frame body 104 is aware of, and (b) the maker or assembler or seller of a frame 102, an appliance, an other device or an object 100 having to anticipate the specifications of any frame body(s) 104, so long as the sleeve 500 is one of specifications respected by the frame body(s) 104. The effect is to have allowed for independence of the maker(s) and assembler(s) and seller(s) of frame body(s) 104 and maker(s) and assembler(s) and seller(s) of frame(s) 102, object(s) 100, appliance(s) and other devices and computers in achieving frame-fittability of variation of frame bodies 104.

Alternatively, the pan 400 as shown in FIGS. 4A and 4B may reside in the sleeve 500 as shown in FIG. 5, or vice versa, in order to facilitate either standardization or customization of the fittability with interchangeable frame body(s) 104.

In some example embodiments, the frame 102 for an object 100 may comprise one or more external modular structure arranged to removably attach to the frame body 104, wherein the external modular structure includes one or more external removable functional modules each arranged to provide the processing or active function to the frame body 104 or the object 100.

In this embodiment, an external removable functional module, for example, which may be a power module 126 or a battery pack arrange to provide additional energy source of the frame 102 or the object 100 to support the processing or active functions of the frame 102 or the object 100. Alternatively, an external removable functional module may be a secondary storage module 118 arranged to provide additional data source or storage capacity for the frame 102 or the object 100.

Alternatively, the external removable functional modules may include at least one of a power module 126, a processing module, a controller module, a core 112, a communication module 114, a display module 116, a storage module 118, an input module 120, an output module, a frame stand 122, a cradle 124 or a space-occupying piece, and the external removable functional module may be arranged to provide processing or active functions of the frame 102 or the object 100, which is similar to the functions provided by the removable functional modules 106 in the previous embodiments.

Alternatively, the external removable functional modules may be operable to interact, or intercommunicate with any other external removable functional modules or the removable functional modules 106 of the frame 102 or the object 100 to provide the processing or active function to the frame body or the object.

In an example embodiment, and with reference to FIGS. 1, 4A and 5, the frame body 104 is powered by an electric current delivered thereto, such that the frame 102 is operable to provide the processing or active function.

As one example, the processing or active function provided by the frame body 104 may be presented in the frame body 104, which is irrespective of any other modules 106 or functionality of the object. The frame may also provide additional functionality complementing the object 100, via a complement comprising an active frame 104 or smart frame 104 and a frame-fittable item 140, for example, a display screen 116 of the appliance or the frame 102.

In this embodiment, the electric current may be delivered to the frame body 104 either by or through or from a frame-fittable item 140, a removable functional module 106 or an external removable functional module. Alternatively, the electric current may be delivered to the frame body 104, as a result of some combination of transmission of current through a frame-fittable item 140, a removable functional module 106 or an external removable functional module, whether originating directly from a power source or, when the frame-fittable item 140, the removable functional module 106 or the external removable functional module, is a complement of a frame 102 or an object 100, through elsewhere in the respective frame 102 or object 100 that has tapped a source of power. Alternatively, the removable functional modules 106 include a power module 126 operable to deliver electric current to the frame body 104.

Alternatively, the power module 126 is an electric current generation apparatus built in or attached to the frame body 104. For example, the frame body 104 is powered by an in-frame or a with-frame power pack, whether comprising one or more batteries or solar energy apparatus or other independent energy-generating apparatus, whether or not rechargeable, or relying on external power.

With the frame body 104 incorporating electrically-powered mechanisms, other electronics (such as a CPU), may be included into the frame body 104, thus turning it into a frame body 104 having a processing power, or any other functionality depending on the nature of the introduced electronics, mechanisms or functional modules.

In an example embodiment, the frame 102 for an object 100 may comprise an identification module arranged to identify a user to personalize the frame 102 in association with the user identification. The identification module may contain a directory of identifiers of the frame 102 or the object 100 which make reference to, for example, but not limited to, a machine-readable or externally readable code, whether within or on any of a frame 102, an object 100, an other device or a computer or a code within software in a frame 102, an object 100, an other device or a computer. Preferably, the code uniquely identifies the respective frame 102 or device or computer or object 100.

By means of an electronic instrument that is securely accessed by the user and that can read a machine-readable or an externally readable code and that has access to a means of communicating with the directory, the user of a frame 102, an object 100, an appliance, an other device or a computer that bears such a code can, casually, relay such an identifier, along with the personal details of the user, from the intermediating trusted instrument, to the directory, in order for the directory to associate the respective frame or appliance and the details entered by the user, for example, via a smartphone or a world-wide-web account, which is accessible via a computing device with access to the world-wide web, or a remote control.

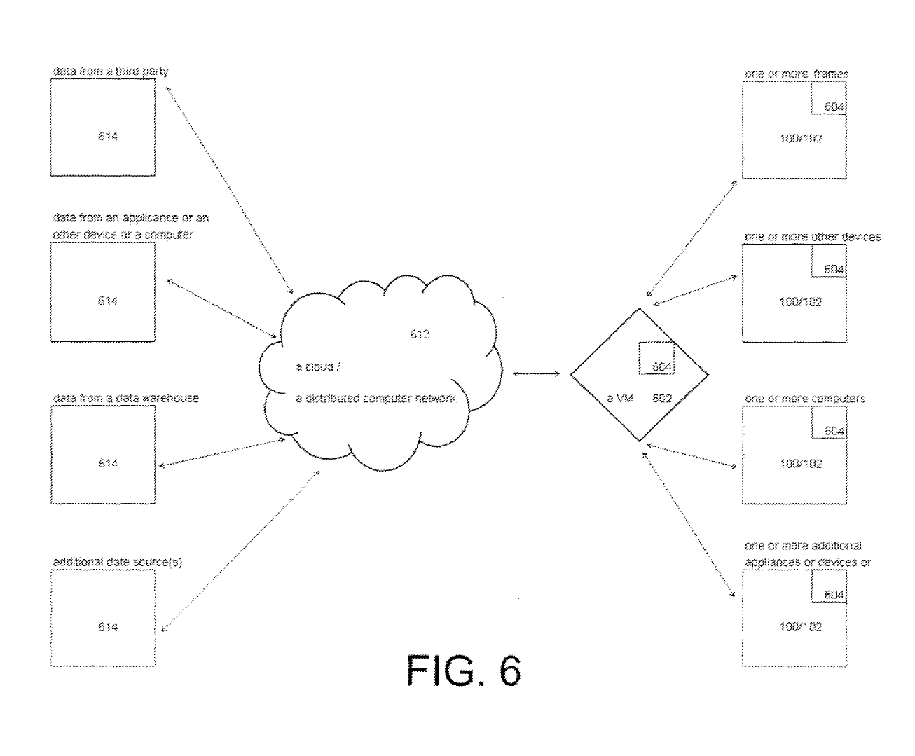

Referring to FIG. 6, there is provided an embodiment of a method for interacting with a frame 102 comprising the steps of: connecting one or more frames 102 via a communication network to form a virtual machine 602; and interacting with the virtual machine 602 to manipulate the processing or active functions of the one or more frames 102 or objects 100.

In this embodiment, one or more frames 102, devices or computers are connected with a communication network, and a virtual machine 602 (VM) is formed. The VM 602 and the one or more frames 102, devices or computers may communicate, whether such communication results from having the VM 602 reside in the one or more frames 102, devices or computers, or takes place remotely, through ordinary means of remote communications, between a VM 602 and a frame or an appliance or an other device or a computer. Preferably, an action or function or purpose can be prescribed by the VM 602 in such a way as to be comprehensible to the frame 102, device or computer with which the VM 602 can communicate. Preferably, the frame 102, device or computer to which the VM 602 pertains has an ability to comply with a prescription by the VM 602 (for example, in (re)organizing the presentation of media on a device or a frame 102). The frame 102, device or computer in such communication network may be considered as a VM receptive with reference to the VM 602 provided.

Alternatively, the method for interacting with a frame 102 may further include a step of connecting the one or more frames to a processing module 604 via the communication network to form the virtual machine 602. For example, one or more frames 102 may connect one or more processing modules 604 resides in an electronic appliance, a device, an object 100, an another frame 102 or a computer, via a communication network, to form a virtual machine 602.

The VM 602 may exist discretely from the pertinent frame(s) 102, object(s) 100, device(s) or computer(s), even when the VM 602 resides on the frame 120, the object 100, the device or the computer. Alternatively, at least a part of the virtual machine 602 resides in at least one of the one or more frames 102.

Preferably, the software code used by the VM 602 doesn't have to be of a particular software language, so far as that the frame 102, device or computer to be affected by the VM 602 can comply with a prescription resulting from the use of that software language.

Additionally, the virtual machine 602 is operable to communicate with at least one distributed computing network 612 arranged to process data before a presentation of the data in at least one of the virtual machine 602, the one or more frames 102 or the objects 100.

With reference to FIG. 6, data may be provided to the virtual machine 602 from one or more sources of data 614, for example, a data warehouse which is different from the frame 102, device or computer, and the data may be processed by such distributed computing network 612, or a cloud computing network, before the data being provided to the virtual machine 602 or the frame 102, device or computer in communication with the virtual machine 602. Alternatively, data resides in the frame 102, device or computer may be processed and provided back to the frame 102, device or computer by the distributed computing network 612 before a presentation of the data in at least one of the virtual machine 602, the one or more frames 102 or the objects 100.

In addition, the frame 102, device or computer may form part of the distributed computing network 612, such that at least a part of the distributed computing network 612 resides in the one or more frames 102 and/or the virtual machine 602.

In manufacturing of a frame 102, an object 100, a device or a computer, modification of these items may be restricted after the completed manufacturing process, or the post manufacture modifications may be either inconvenient or uneconomical. For example, such frames 102, objects 100, devices or computers of the same purpose or category or class may have a boring look, due to high degree of uniformity, imposed by lack of convenience or economy in modifying them, whether in a late stage of manufacture or in assembly or in post-manufacture. In some occasions, such frames 102, objects 100, devices or computers, generally, can't be noticeably varied post-manufacture, without much effort, whether by a person, whether a maker or mercantile or a consumer, to meet different criteria of economics (for example, with regard to costs of delivering different versions of an appliance), aesthetics and/or other preferences.

Some devices such as a digital photo frame, or a device relating to media, may rely on some kind of code to purpose each appliance. Often, such code is firmware. It may be specific to any of, for example, an appliance or a line of different models of appliance or a class of appliance.

These embodiments are advantageous in that an object 100 may be modified, by customizing the different functional modules of the object, including the frame body 104, the internal/external components or modules, as well as the cables 132 and the connectors 134. For example, some embodiments of achieving separability of a frame body 104 and frame-fittable item 140 can accommodate a variety of form factors of frame body 104 and frame-fittable item 140. Such separability may deliver the effect that a person, whether a maker or mercantile or a consumer, to interchange frames body 104, as they become available to him/her/it, without abandoning a frame body 104 or a frame-receptive item, and the effect of interchangeability can widely expand the variety of frame bodies 104, which may come from alternative makers other than the assembler of the rest of the frame 102, device or object 100.

Advantageously, making key physical components of a frame 102, an appliance, a device or an object 100 be replaceable internally or externally from the device or the object 100 renders, in respect of a frame 102, an appliance, a device or an object 100, an internally or externally refittable modularity of such components, whether to be apart from each other or to be snugly fitting among themselves, like pieces of a complete puzzle, or with some of those components to be apart from others and some to be snugly fitting among themselves, so that each such component is attachable and removable.

By achieving modularity, these embodiments may deliver one or more of a diversity of several effects, for example, while not limited to, an improvement in cost-efficiency in making or assembling or configuring a frame 102, an object 100, a device or a computer. These embodiments may provide more choices for a consumer to obtain a different configuration of a frame 102, an object 100, a device or a computer of a certain class of such (for example, to add a certain communications feature) without having to abandon that frame 102, object 100, device or a computer, the customer or the manufacturer may update of key components without wasting other modules such as the removable functional modules 106.

These embodiments may allow for upgrading a frame 102, an object 100, a device or a computer on the basis of replacing one or more different modules with an improved version of that module without having to replace, and thus to dispose of, the entire appliance, the frame 102 or the object 100.

These embodiments are also advantageous in that, such separability delivers the effect that a person, whether a maker or mercantile or a consumer, to interchange frame bodies 104, as they become available to him/her/it, without abandoning a frame 102, a frame body 104 or a frame-receptive item.

Advantageously, frame bodies 104 that are electrically powered may be active or smart, and these smart frames 104 are applicable broadly to any frame-fittable items 140, whether or not a device relating to media, for example, while not limited to, as a part of eyeglasses, whether prescription or HD/3D, or television sets, monitors, digital photo frames or billboards or as a part of a piece of luggage or as a part of a piece of furnishings. Such active or smart frames 104 can become objects of amusement and/or promotion, e.g. advertising, and/or functionality (for example, by utilizing NFC or a motion/light sensor or illumination).

In some of the embodiments of the attachment means as shown in FIGS. 3A to 3D, these embodiments are advantageous in that separability between two or more removable functional modules 106, or between a frame body 104 and a frame-fittable item 140 in an object 100 or a frame 102, for example, an instrument of display 116 of content and the respective frame body 104 of an object 100 or a frame 102. Modules and frame bodies with such attachment means may allow functional modules to be changed or switched when the frame 102, object 100, device or computer is customized.

In some embodiments, by including a modifiable power cord 130 or cable 132, a frame 102, an object 100, a device or a computer may be customized for different users and applications. The power cord 130 or cable 132 may be customized by changing the separable connectors 134 and different encapsulations, so as to fit with different application such as different power adapters 136 with different connectors, or the colour/material/length of the encapsulations may be varied for different preferences of different users.

Advantageously, some embodiments of the frame 102, the object 100, the device or the computer may allow for personalization of one or more features or functions of the frame 102, object 100, device or computer, including but not limited to, services accessible through the appliance, without having to put personal details of the user into that frame 102, object 100, device or computer, thus achieving personalization while maintaining confidence of the user without implanting personal details of the user in the target frame 102, object 100, device or computer.

With reference to FIG. 6, the frames 102, objects 100, devices or computers may operate/manipulate a virtual machine 602 which may be modified after the manufacturing process. For example, a person, whether a maker or mercantile or a consumer, or a machine to update the VM 602, whether remotely or directly. In addition, a person, whether a maker or mercantile or a consumer, may run a copy of the VM 602, on a VM-receptive, including the frame 102, object 100, device or computer (for example, suitable “smartphones”, “tablets” and other computers), as well as on any other device known by a person skilled in the art.

The person may emulate some performance of an action or a function by utilizing a VM 602 in accordance with one of the embodiments provided. The person may affect, some other VM-resident appliance(s) or frame(s) 102, object(s) 100, device(s) or computer(s) via some or another means of ordinarily available communications between a VM 602 on one appliance or frame 102, object 100, device or computer and a congruent VM 602 on another frame 102, object 100, device or computer. The person may also put a VM-resident frame 102, object 100, device or computer, instantly into some alternative states, including but not limited to, a passive receptacle of data such as content or records or instruction(s) presented by means of machine-to-machine communication arranged for by the VM 602, an interactive receptacle of such data introduced by any person between whom and the frame 102, object 100, device or computer there is direct communication, or a publisher of such data to one or more other frames 102, objects 100, devices or computers. These states may be selectable by, for example, either touching a button or a symbol of the command of the state, or reference by the VM 602 to a set of rules or a remote command.

Advantageously, a person, whether a maker or mercantile or a consumer, already having an appliance, a frame 102, an object 100, a device or a computer receptive to the VM 602, may either retrofit the VM 602 to/into the appliance, frame 102, object 100, device or computer, where the appliance, frame 102, object 100, device or computer lacks the VM 602, or to update the VM 602, where a version of it already resides in the appliance, frame 102, object 100, device or computer.

The virtual machine 602 complemented by the distributed computer network 612 is advantageous in that, mitigating a need to process such data, in relation to a prescription to be made by the VM 602, on an appliance, a frame 102, an object 100, a device or a computer to which the VM 602 pertains, substantially widens the range of appliances, frames 102 or objects 100 that can benefit from utilization of the VM 602.

In one example embodiments, and with reference to FIG. 1, a device relating to media 100 is provided in accordance with one or more previous embodiments, comprising: at least one frame 102 with the possibility of a suite of frame bodies 104 to switch among; at least one instrument of display 116, or even more different instruments of display 116 to switch among, the instrument of display 116 may resides within a sleeve 500, a pan 400 or both; a core 112 containing a VM 602; a network module 114 including at least one of a SIM apparatus container, a network-adaptor(s) apparatus container or a NFC apparatus container, or a container encompassing two or more of the SIM apparatus and network adaptor(s) apparatus and NFC or some combination of the permutations; a power-pack 126 container including any one of an AC-DC transformer, one or more batteries, or solar-energy apparatus; a stand 122 or a cradle 124 which is fixed or adjustable; a power cord 130 with separable connectors 134 and arranged to connect with a transformer 136 with a plug 138; and an identification module operable to identify machine-readable and/or externally readable codes.

Without deviating from the spirit of the invention, the frame for an object may be built in or fittable with any object. These objects may be any devices relating to media, including but not limiting to, photo frames, appliances that display digital photographs on an electronic screen, monitors, computers that present media, handsets of telephony, portable music players, television sets, certain wearable personal accessories, smart glasses, billboards (whether analog or digital) or any other appliances to do with media.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

Any reference to prior art contained herein is not to be taken as an admission that the information is common general knowledge, unless otherwise indicated.

1. A frame for an object comprising: a frame body arranged to removably engage, support or operate with the object, wherein the frame body includes one or more functional modules each arranged to provide a processing or active function to the frame body or the object when the frame is engaging, supporting or operating with thereof; and wherein the frame body is further arranged to at least partially encompass or surround the object.

2. A frame in accordance with claim 1, wherein at least two of the one or more functional modules are further arranged to interact with each other to provide the processing or active function to the frame body or the object.

3. A frame in accordance with claim 1, wherein at least two of the one or more functional modules are arranged to intercommunicate with each other so as to provide a modular functional arrangement.

4. A frame in accordance with claim 1, wherein the frame body is powered by an electric current delivered thereto to provide the processing or active function to the frame body or the object.

5. A frame in accordance with claim 4, wherein the functional modules include a power module operable to deliver the electric current to the frame body.

6. A frame in accordance with claim 1, wherein the one or more functional modules includes a frame-fittable item being dimensioned to fit the frame body.

7. A method for interacting with a frame in accordance with claim 1, comprising the steps of:
connecting one or more frames via a communication network to either form or augment a virtual machine; and
interacting with the virtual machine to manipulate the processing or active functions of the one or more frames or objects.

8. A method for interacting with a frame in accordance with claim 7, further including a step of connecting the one or more frames to a processing module via the communication network to form the virtual machine.

9. A method for interacting with a frame in accordance with claim 7, wherein at least a part of the virtual machine resides in at least one of the one or more frames.

10. A method for interacting with a frame in accordance with claim 7, wherein the virtual machine is operable to communicate with at least one distributed computing network arranged to process data before a presentation of the data in at least one of the virtual machine, the one or more frames or the objects.

11. A method for interacting with a frame in accordance with claim 10, wherein at least a part of the distributed computing network resides in the one or more frames and/or the virtual machine.

12. A frame in accordance with claim 6, further comprises an attachment means arranged to removably engage the frame-fittable item to the frame body.

13. A frame in accordance with claim 12, wherein the attachment means is provided on one or more positions of at least one of the frame body, or the frame-fittable item, wherein the one or more positions include at least one of an edge, a surface or a spot.

14. A frame in accordance with claim 12, wherein the attachment means include at least one of a reversible tongue-and-groove fitting, a soft fastener, a sticky substance, an organic medium with separable adhesion, a magnetic medium or an electro-magnetic medium.

15. A frame in accordance with claim 6, wherein the one or more functional modules are contained in a pan having a dimension which fits the frame body.

16. A frame in accordance with claim 6, wherein one or more functional modules are sleeved in a structure having a dimension which fits the frame body.

17. A frame in accordance with claim 1, further comprising an external modular structure arranged to removably attach to the frame body, wherein the external modular structure is arranged to include the one or more external functional modules each arranged to provide the processing or active function to the frame body or the object.

18. A frame in accordance with claim 1, wherein the one or more functional modules include at least one of a power module, a processing module, a controller module, a communication module, a display module, a storage module, an input module, an output module, a frame stand, or a space-occupying piece.

19. A frame in accordance with claim 1, wherein the frame body is removably attach to a removable stand, and wherein the removable stand is manually or automatically expandable to accommodate a change in size of a part or an entire frame body.

20. A frame in accordance with claim 1, further comprising a cable operable to deliver electric current thereto, wherein the cable comprises one or more connectors and an encapsulation arrange to encapsulate the cable, and wherein the one or more connectors and the cable are separable among each other.

21. A frame in accordance with claim 20, wherein the encapsulation is electronically controllable.

22. A frame in accordance with claim 1, further comprises an identification arrangement arranged to facilitate the association of an identity of a user of the frame to an identity of the frame.

23. A frame in accordance with claim 22, wherein the identification arrangement is arranged to associate the identity of the user to the identity of the frame by obtaining a user identifier via an external authenticated device.

24. A frame in accordance with claim 1, wherein the frame body is arranged to operate with the object via a wireless communication network between the frame body and the object.

25. A frame in accordance with claim 1, wherein the frame body is arranged to operate with the object without a physical contact or engagement.
